(19) United States
(12) Patent Application Publication
(10) Pub. No.: US 2020/0144324 A1
(43) Pub. Date: May 7, 2020

(54) PIXEL UNIT, IMAGE SENSOR, MANUFACTURING METHOD THEREOF AND IMAGING DEVICE

(71) Applicant: HUAIAN IMAGING DEVICE MANUFACTURER CORPORATION, HUAIAN (CN)

(72) Inventors: Chao ZHANG, HUAIAN (CN); Xinyi HUANG, HUAIAN (CN)

(73) Assignee: HUAIAN IMAGING DEVICE MANUFACTURER CORPORATION, HUAIAN (CN)

(21) Appl. No.: 16/522,448

(22) Filed: Jul. 25, 2019

(30) Foreign Application Priority Data
Nov. 6, 2018 (CN) 201811310220.9

(51) Int. Cl. H01L 27/146; H04N 5/369; H04N 9/04; G01J 1/44; G01J 1/42

(52) U.S. Cl. CPC H01L 27/14645; H01L 27/14621; H01L 27/14605; H01L 27/14625; G01J 2001/448; H04N 5/379; H04N 9/0451; G01J 1/44; G01J 1/4228; H01L 27/14683

(57) ABSTRACT

An image sensor including a pixel array, the pixel array includes alternately distributed first pixel units and second pixel units, the first pixel unit includes a first radiation sensing element for sensing the radiation in a first wavelength range, and a second radiation sensing element for sensing the radiation in a second wavelength range different from the first wavelength range, in which the first radiation sensing element is separated from the second radiation sensing element, and the second pixel unit includes a third radiation sensing element for sensing the radiation in the third wavelength range, which is different from the first wavelength range and the second wavelength range, and a fourth radiation sensing element for sensing the radiation in the second wavelength range, in which the third radiation sensing element is separated from the fourth radiation sensing element.

### CROSS-REFERENCE TO RELATED APPLICATIONS

This disclosure claims priority to Chinese Patent Application No. 201811310220.9, filed on Nov. 6, 2018, which is hereby incorporated by reference in its entirety.

### TECHNICAL FIELD

The present disclosure relates generally to the field of semiconductor technology, and more particularly, to a pixel unit, an image sensor, a manufacturing method thereof and an imaging device.

### BACKGROUND

Image sensors can be used to sense radiation (e.g., light radiation, including but not limited to visible light, infrared light, ultraviolet light, X-ray, etc.) to generate corresponding electrical signals (e.g., images). It is widely used in digital cameras, mobile communication terminals, security facilities and other imaging devices.

Nowadays, Bayer-mode pixel arrays are commonly used in image sensors. In Bayer mode, each pixel senses the radiation of only one primary color, and the radiation values of the other two primary colors of the pixel are calculated by interpolating the radiation values sensed by the surrounding pixels. Therefore, the resulting image will lose some image details and cause color aliasing.

Therefore, it is necessary to propose a new technology to solve one or more of the problems in the prior art.

### SUMMARY

One aspect of this disclosure is to provide a pixel unit comprising: a first radiation sensing element for sensing the radiation in the first wavelength range; and a second radiation sensing element for sensing the radiation in a second wavelength range different from the first wavelength range, in which the first radiation sensing element is separated from the second radiation sensing element.

The above pixel unit may further comprise a radiation filter located above the first radiation sensing element. The radiation filter allows the radiation in the first and second wavelength ranges to pass through and filters out the radiation in the third wavelength range, which is different from the first and second wavelength ranges.

In the above pixel unit, the first radiation sensing element is formed in the first substrate, the second radiation sensing element is formed in the second substrate separated from the first substrate, and the first radiation sensing element is located above the second radiation sensing element.

The above pixel unit may further comprise a light tube formed between the first substrate and the second substrate. The light tube separates the first radiation sensing element from the second radiation sensing element.

In the above pixel unit, the radiation is the visible light, and the first wavelength range includes the wavelengths of one of the green light and blue light. The second wavelength range includes the wavelengths of the red light, and the third wavelength range includes the wavelengths of the other of the green light and blue light.

The above pixel unit may further comprise a first charge accumulation element for accumulating the charges generated by the first radiation sensing element; and a second charge accumulation element for accumulating the charges generated by the second radiation sensing element.

Another aspect of this disclosure is to provide an image sensor including a pixel array, the pixel array includes alternately distributed first pixel units and second pixel units, the first pixel unit includes: a first radiation sensing element for sensing the radiation in a first wavelength range; and a second radiation sensing element for sensing the radiation in a second wavelength range different from the first wavelength range, in which the first radiation sensing element is separated from the second radiation sensing element, the second pixel unit includes: a third radiation sensing element for sensing the radiation in the third wavelength range, which is different from the first wavelength range and the second wavelength range; and a fourth radiation sensing element for sensing the radiation in the second wavelength range, in which the third radiation sensing element is separated from the fourth radiation sensing element.

Another aspect of this disclosure is to provide an imaging device includes an image sensor as described above.

Another aspect of this disclosure is to provide a method for forming an image sensor comprising: providing a first substrate in which a plurality of first radiation sensing elements and a plurality of third radiation sensing elements are formed; providing a second substrate in which a plurality of second radiation sensing elements and a plurality of fourth radiation sensing elements are formed; and bonding the first substrate above the second substrate, wherein each of the first radiation sensing elements senses the radiation in the first wavelength range, each of the second radiation sensing elements and each of the fourth radiation sensing elements sense the radiation in a second wavelength range different from the first wavelength range, each of the third radiation sensing elements senses the radiation in the third wavelength range, which is different from the first and second wavelength ranges, and wherein, the first radiation sensing element in the first substrate and the corresponding second radiation sensing element in the second substrate under the first radiation sensing element constitute the first pixel unit, and the third radiation sensing element in the first substrate and the corresponding fourth radiation sensing element in the second substrate under the third radiation sensing element constitute the second pixel unit, and the first pixel unit and the second pixel unit are alternately arranged as a pixel array.

Further features of the present disclosure and advantages thereof will become apparent from the following detailed description of exemplary embodiments with reference to the attached drawings.

### BRIEF DESCRIPTION OF THE DRAWINGS

The accompanying drawings, which constitute a part of the specification, illustrate embodiments of the present disclosure and, together with the description, serve to explain the principles of the present disclosure.

The present disclosure will be better understood according the following detailed description with reference of the accompanying drawings.

FIG. 1 is a schematic diagram of a pixel array based on the Bayer mode of the prior art.

FIG. 2 is a schematic diagram of the stacking structure of the Foveon X3 sensor according to the prior art.

FIG. 3 is a sectional structure diagram of a pixel unit in accordance with some embodiments of the present disclosure.

FIG. 4 is a partial sectional diagram of an image sensor according to some embodiments of the present disclosure.

FIG. 5 is a schematic diagram of a pixel array of an image sensor according to some embodiments of the present disclosure.

FIG. 6 is a schematic diagram of a pixel array of an image sensor in accordance with some embodiments of the present disclosure.

FIG. 7 is a flowchart of a method for forming an image sensor in accordance with some embodiments of the present disclosure.

Note that, in the embodiments described below, in some cases the same portions or portions having similar functions are denoted by the same reference numerals in different drawings, and description of such portions is not repeated. In some cases, similar reference numerals and letters are used to refer to similar items, and thus once an item is defined in one figure, it need not be further discussed for following figures.

In order to facilitate understanding, the position, the size, the range, or the like of each structure illustrated in the drawings and the like are not accurately represented in some cases. Thus, the disclosure is not necessarily limited to the position, size, range, or the like as disclosed in the drawings and the like.

### DETAILED DESCRIPTION

Various exemplary embodiments of the present disclosure will be described in details with reference to the accompanying drawings in the following. It should be noted that the relative arrangement of the components and steps, the numerical expressions, and numerical values set forth in these embodiments do not limit the scope of the present disclosure unless it is specifically stated otherwise.

The following description of at least one exemplary embodiment is merely illustrative in nature and is in no way intended to limit this disclosure, its application, or uses. That is to say, the structure and method discussed herein are illustrated by way of example to explain different embodiments according to the present disclosure. It should be understood by those skilled in the art that, these examples, while indicating the implementations of the present disclosure, are given by way of illustration only, but not in an exhaustive way. In addition, the drawings are not necessarily drawn to scale, and some features may be enlarged to show details of some specific components.

Techniques, methods and apparatus as known by one of ordinary skill in the relevant art may not be discussed in detail, but are intended to be regarded as a part of the specification where appropriate.

In all of the examples as illustrated and discussed herein, any specific values should be interpreted to be illustrative only and non-limiting. Thus, other examples of the exemplary embodiments could have different values.

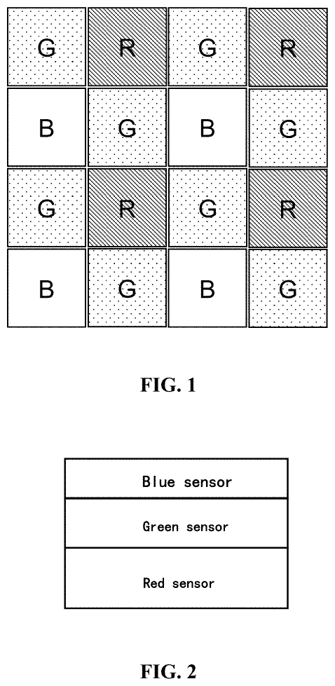

Traditionally, Bayer-mode pixel arrays have been used in image sensors, such as CMOS image sensors (CIS) products. FIG. 1 shows an example of a Bayer mode pixel array in which G represents green pixels, R represents red pixels, and B represents blue pixels. In the Bayer mode, each pixel senses the radiation of only one primary color, and the radiation values of the other two primary colors of the pixel are calculated by interpolating the radiation values sensed by the surrounding pixels. Therefore, the resulting image will lose some image details and cause color aliasing, so the authenticity of the image will be impaired.

A sensor stack structure called Foveon X3 has been proposed, in which each pixel unit contains three sensors, each sensor senses the radiation of different primary colors, respectively. FIG. 2 shows a schematic diagram of a stack structure of Foveon X3 sensors, in which blue, green and red sensors are arranged from top to bottom in a single substrate (e.g., silicon substrate) in order. In Foveon X3 structure, there is no filter for filtering the radiation. Because the depths of light of different wavelengths at which it is absorbed by the substrate when it propagates in the substrate are different, and the longer the wavelength, the greater the depth at which it is absorbed, so the blue sensor is arranged in the top layer, followed by the green sensor and the red sensor.

Because each pixel in the Foveon X3 sensor structure can sense three different primary colors of radiation, there is no need to calculate the interpolation of each pixel's color value. However, the inventor of the present application finds that in the Foveon X3 structure, since sensors of different colors are stacked on a same substrate adjacent to each other, the photoelectrons generated in an area between adjacent sensors (e.g., between green sensors and red sensors) may flow to the upper sensor and may also flow to the lower sensor. Therefore, the crosstalk between the pixel signals of different colors is large.

In order to improve one or more of the above technical problems existing in the prior art, the inventor of the present application proposes a new technical idea: to set two radiation sensing elements in one pixel and separate the two radiation sensing elements.

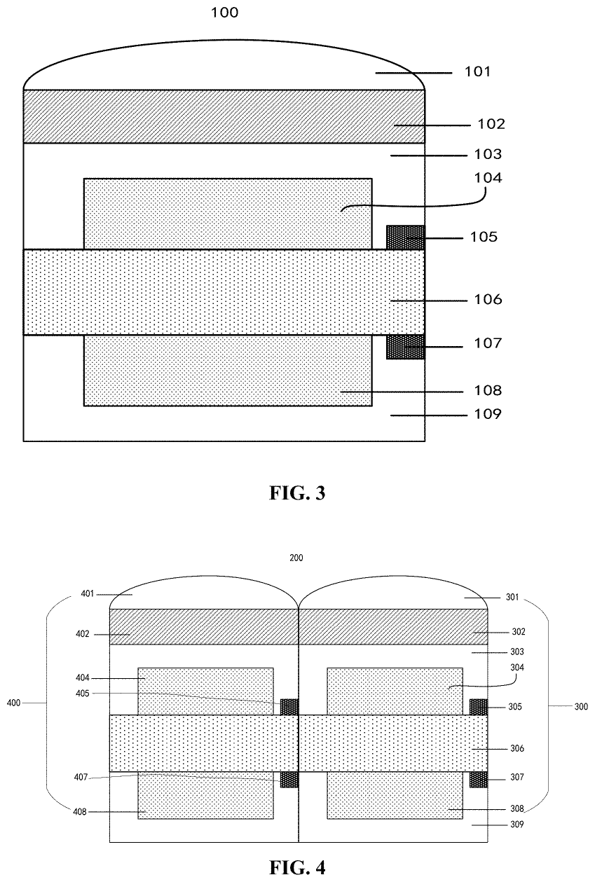

FIG. 3 is a sectional structure diagram of the pixel unit 100 according to some embodiments of the present disclosure. The pixel unit 100 includes a first radiation sensing element 104 and a second radiation sensing element 108. The first radiation sensing element 104 is used for sensing the radiation in a first wavelength range (e.g., light radiation, including but not limited to visible light, infrared light, ultraviolet light, etc.), and the second radiation sensing element 108 is used for sensing the radiation in a second wavelength range different from the first wavelength range. The first radiation sensing element 104 and the second radiation sensing element 108 are separated from each other. Since these two radiation sensing elements are separated, the charge generated by radiation (e.g., photoelectrons) near the first radiation sensing element 104 will not flow to the second radiation sensing element 108, and vice versa. Therefore, the signal crosstalk between the radiation sensing elements can be effectively suppressed.

The radiation sensing elements in the present disclosure are, for example, optical sensing elements (e.g., photodiodes).

In some embodiments, the wavelengths in the first wavelength range are shorter than those in the second wavelength range.

In some embodiments, a radiation filter 102 is formed above the first radiation sensing element 104, which allows the radiation in the first and second wavelength ranges to pass through and filters out the radiation in a third wavelength range, which is different from the first and second wavelength ranges. Since a radiation filter 102 is formed above the first radiation sensing element 104 to filter out the radiation in the third wavelength range, the pixel unit 100 can avoid the signal crosstalk caused by the radiation in the third wavelength range being sensed by the first radiation sensing element 104 and the second radiation sensing element 108.

In some embodiments, the wavelengths in the third wavelength range are shorter than those in the second wavelength range.

In some embodiments, the first radiation sensing element 104 is formed in a first substrate 103, the second radiation sensing element 108 is formed in a second substrate 109 separated from the first substrate 103, and the first radiation sensing element 104 is located above the second radiation sensing element 108. Since the first radiation sensing element 104 is located above the second radiation sensing element 108, the radiation that is incident downward from the radiation filter 102 into the first substrate 103 can be incident into the second substrate 109 and be sensed by the second radiation sensing element 108 in the second substrate 109 after passing through the first substrate 103. Thus, the pixel unit 100 can sense the radiation in two wavelength ranges (the first wavelength range and the second wavelength range). In addition, since the first substrate 103 is separated from the second substrate 109, the charge generated by radiation in the first substrate 103 can hardly flow to the second substrate 109, and vice versa. Therefore, the crosstalk between the radiation sensing elements in the same pixel unit is further suppressed.

In some embodiments, the first substrate 103 and the second substrate 109 may be composed of suitable one-component semiconductor materials (such as silicon or germanium) or compound semiconductors (such as silicon carbide, silicon germanium, gallium arsenide, gallium phosphide, indium phosphide, indium arsenide and/or indium antimony) or combinations thereof. The materials of the first substrate 103 and the second substrate 109 may be the same or different. In addition, for example, the first substrate 103 and the second substrate 109 may employ SOI (silicon on insulators) substrates or any other suitable material.

In some embodiments, the pixel unit 100 may also include a light tube 106 formed between the first substrate 103 and the second substrate 109, which separates the first radiation sensing element 104 from the second radiation sensing element 108. The light tube 106 can guide the radiation passing through the first substrate 103 from top to bottom into the second substrate 109. In some embodiments, the light tube 106 is formed from an organic polymer and can converge the radiation. As understood by those skilled in the field, light tubes may employ any suitable product or technology known in the field or that may emerge in the future.

In some embodiments, the radiation refers to the visible light. The first wavelength range includes the wavelengths of one of the green light and the blue light, the second wavelength range includes the wavelengths of the red light, and the third wavelength range includes the wavelengths of the other of the green light and the blue light. In these embodiments, the pixel unit 100 is capable of sensing the red light and one of the green light and the blue light.

In some embodiments, the pixel unit 100 can sense both the green light and the blue light, but not red light.

In some embodiments, the pixel unit 100 may further includes: a first charge accumulation element 105 for accumulating charges generated by the first radiation sensing element 104; and a second charge accumulation element 107 for accumulating charges generated by the second radiation sensing element 108. In some embodiments, the first charge accumulation element 105 and the second charge accumulation element 107 are, for example, floating diodes. In some embodiments, the first charge accumulation element 105 is formed in the first substrate 103 and the second charge accumulation element 107 is formed in the second substrate 109. Since the charge accumulation elements are arranged in the first radiation sensing element 104 and the second radiation sensing element 108 respectively, the charges sensed by the first radiation sensing element 104 and the second radiation sensing element 108 can be read out respectively, thereby preventing signal crosstalk.

In some embodiments, the thicknesses of the first substrate 103 and the second substrate 109 are between 1.2 and 1.8 microns.

In some embodiments, a microlens 101 is further provided above the radiation filter 102. The microlens 101 can converge the radiation incident on it.

In some embodiments, metal interconnections (not shown) are further provided between the first substrate 103 and the second substrate 109 to achieve electrical connections between components.

FIG. 4 shows a partial sectional diagram of an image sensor 200 according to some embodiments of the present disclosure, which shows only one first pixel unit 300 and one second pixel unit 400 for clarity. In some embodiments, the image sensor 200 may include a pixel array formed by alternately distributed first and second pixel units 300 and 400. The basic structures of the first pixel unit 300 and the second pixel unit 400 are the same as those of the above-mentioned pixel unit 100, but the wavelength ranges of the radiation sensed by the first pixel unit 300 and the second pixel unit 400 may be different.

In some embodiments, the first pixel unit 300 includes a first radiation sensing element 304 for sensing the radiation in the first wavelength range and a second radiation sensing element 308 for sensing the radiation in the second wavelength range different from the first wavelength range, wherein the first radiation sensing element 304 and the second radiation sensing element 308 are separated from each other. The second pixel unit 400 includes: a third radiation sensing element 404 for sensing the radiation in the third wavelength range, the third wavelength range being different from the first and second wavelength ranges; and a fourth radiation sensing element 408 for sensing the radiation in the second wavelength range, wherein the third radiation sensing element 404 and the fourth radiation sensing element 408 are separated from each other.

Since the two radiation sensing elements in each pixel unit are separated from each other, the charge generated by radiation (e.g., photoelectrons) near one radiation sensing element will not flow to another radiation sensing element, and vice versa. Therefore, the signal crosstalk between radiation sensing elements in the same pixel unit can be effectively suppressed. Therefore, compared with the stacked structure of Foveon X3 sensor, the image sensor in the present disclosure can significantly suppress signal crosstalk between the radiation sensing elements while maintaining better image authenticity.

In some embodiments, the wavelengths of the first wavelength range and the third wavelength range are shorter than those of the second wavelength range.

In some embodiments, the first pixel unit 300 may further include a radiation filter 302 located above the first radiation sensing element 304, which allows the radiation in the first and second wavelength ranges to pass through and filters out the radiation in the third wavelength range. The second pixel unit 400 may further include a radiation filter 402 located above the third radiation sensing element 404, which allows the radiation in the third and second wavelength ranges to pass through and filters out the radiation in the first wavelength range.

Due to the formation of radiation filters 302 and 402, the image sensor of the present disclosure can further avoid the signal crosstalk caused by the radiation of the wavelength range as filtered out being sensed by the two radiation sensing elements located below the radiation filter, respectively.

In some embodiments, the first radiation sensing element 304 and the third radiation sensing element 404 may be formed in the first substrate 303, and the second radiation sensing element 308 and the fourth radiation sensing element 408 may be formed in the second substrate 309 separated from the first substrate 303. The first radiation sensing element 304 is above the second radiation sensing element 308, and the third radiation sensing element 404 is above the fourth radiation sensing element 408.

In some embodiments, the image sensor 200 may further include a light tube 306 formed between the first substrate 303 and the second substrate 309, which separates the first radiation sensing element 304 from the second radiation sensing element 308, and separates the third radiation sensing element 404 from the fourth radiation sensing element 408. The light tube 306 can guide the radiation passing through the first substrate 303 from top to bottom into the second substrate 309, so that the corresponding radiation can be sensed by the second radiation sensing element 308 or the fourth radiation sensing element 408 in the second substrate 309.

In some embodiments, the radiation is the visible light, the first wavelength range includes the wavelengths of the green light, the second wavelength range includes the wavelengths of the red light, and the third wavelength range includes the wavelengths of the blue light.

Since each pixel unit in the present disclosure can sense the radiation in two wavelength ranges (e.g., the visible light of two primary colors), the image sensor composed of the pixel units of the present disclosure can obtain a more realistic picture than the pixel unit in Bayer mode.

Furthermore, in the image sensor disclosed herein, for each pixel unit, only one color interpolation value (e.g., the green or blue signal interpolation value) of the principle color not sensed by the pixel unit is required. Therefore, the color interpolation algorithm for the image sensor disclosed in this disclosure can be simplified compared with the case in which two color interpolation values of two primary colors are needed to be obtained for each pixel unit in Bayer mode.

In some embodiments, the image sensor 200 may further include: a first charge accumulation element 305 for accumulating charges generated by the first radiation sensing element 304; a second charge accumulation element 307 for accumulating charges generated by the second radiation sensing element 308; a third charge accumulation element 405 for accumulating charges generated by the third radiation sensing element 404; and a fourth charge accumulation element 407 for accumulating charges generated by the fourth radiation sensing element 408. In some embodiments, these charge accumulation elements are, for example, floating diodes. In some embodiments, the first charge accumulation element 305 and the third charge accumulation element 405 may be formed in the first substrate 303, and the second charge accumulation element 307 and the fourth charge accumulation element 407 may be formed in the second substrate 309.

In some embodiments, the first radiation sensing element 304 and the third radiation sensing element 404 may share one charge accumulation element, and the charges generated by the first radiation sensing element 304 and the third radiation sensing element 404 may be accumulated into the shared one charge accumulation element. In some embodiments, whether the charges are accumulated for the first radiation sensing element 304 or for the third radiation sensing element 404 may be switched by setting switches for the first radiation sensing element 304 and the third radiation sensing element 404, respectively.

Similarly, the second radiation sensing element 308 and the fourth radiation sensing element 408 can share one charge accumulation element, and the charges generated by the second radiation sensing element 308 and the fourth radiation sensing element 408 may be accumulated into the shared one charge accumulation element. In some embodiments, whether the charges are accumulated for the second radiation sensing element 308 or for the fourth radiation sensing element 408 may be switched by setting switches for the second radiation sensing element 308 and the fourth radiation sensing element 408, respectively.

In some embodiments, the thicknesses of the first substrate 303 and the second substrate 309 range from 1.2 to 1.8 microns.

In some embodiments, a microlens 301 is arranged above the radiation filter 302 and a microlens 401 is arranged above the radiation filter 402. The microlenses 301 and 401 can converge the radiation incident on them.

In some embodiments, a metal interconnection (not shown) is further provided between the first substrate 303 and the second substrate 309 for transmitting the charges generated by the radiation sensing elements.

In some embodiments, the light tube 306 may be composed of upper and lower parts, that is, upper and lower light tube parts. In some embodiments, the first substrate 303 may be bonded to the upper surface of the upper tube part, the second substrate 309 may be bonded to the lower surface of the lower tube part, and the lower surface of the upper tube part and the upper surface of the lower tube part may be bonded together.

In some embodiments, an isolation component (not shown) is further provided between the first pixel unit 300 and the second pixel unit 400 to prevent radiation propagating in one pixel unit from propagating into another pixel unit. In some embodiments, the isolation component can prevent charges generated in one pixel unit from flowing into another pixel unit.

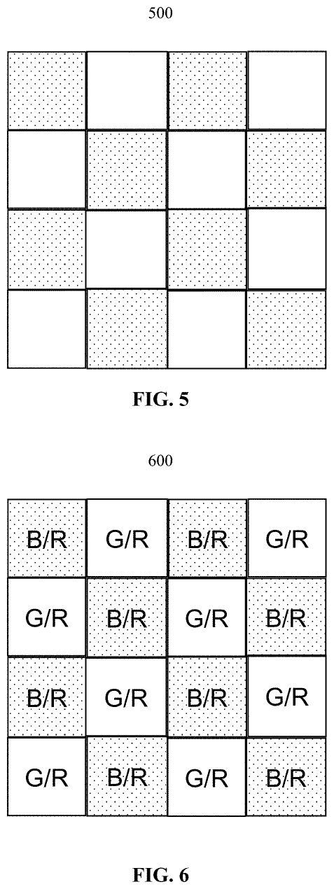

FIG. 5 shows a schematic diagram of the pixel array 500 of the image sensor 200 according to some embodiments of the present disclosure. The pixel array 500 may be formed by alternately distributed first pixel unit 300 (represented by a blank lattice in the figure) and second pixel unit 400 (represented by a lattice with a filling pattern in the figure).

FIG. 6 shows a schematic diagram of a pixel array 600 of an image sensor 200 according to other embodiments of the present disclosure. In these embodiments, the radiation is the visible light, the first pixel unit 300 is used to detect the green and red light, which is represented by “G/R” in FIG. 6, and the second pixel unit 400 is used to detect the blue and red light, which is represented by “B/R” in FIG. 6. The pixel array 600 may be formed by alternately distributed first and second pixel units 300 and 400.

In some embodiments, the present disclosure also includes an imaging device (not shown), which includes the image sensor 200 as described above. The imaging device may also include a lens for converging external radiation and guiding it to the image sensor 200.

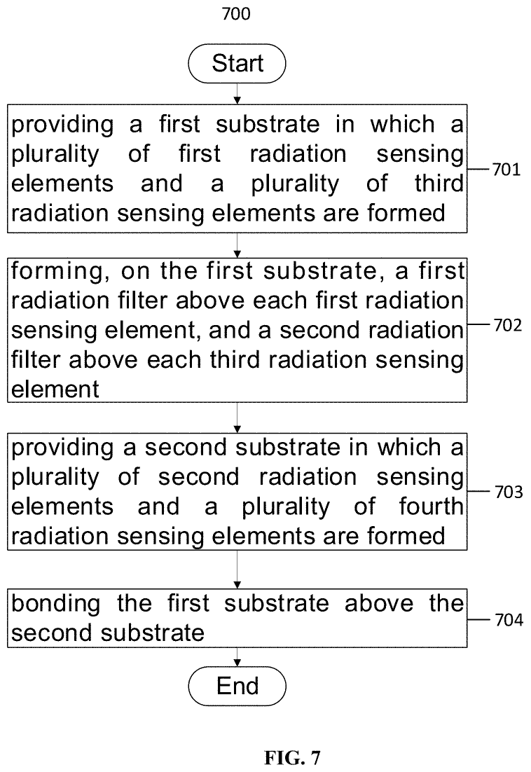

The present disclosure also includes a method 700 for forming an image sensor 200. FIG. 7 shows the flow chart of the method. The steps of the method are described below in conjunction with the flow chart. In step 701, a first substrate is provided, in which a plurality of first radiation sensing elements and a plurality of third radiation sensing elements may be formed. As understood by those skilled in the art, any suitable method may be used to form a radiation sensing element.

The method 700 also includes step 703, in which a second substrate is provided, in which a plurality of second radiation sensing elements and a plurality of fourth radiation sensing elements may be formed.

The method 700 also includes step 704, in which the first substrate is bonded above the second substrate. In some embodiments, the first and second substrates are bonded by wafer bonding processing. The wafer bonding processing may be, for example, a copper-copper bonding processing.

In some embodiments, each first radiation sensing element is used to sense the radiation in the first wavelength range, each second radiation sensing element and each fourth radiation sensing element is used to sense the radiation in the second wavelength range different from the first wavelength range, and each third radiation sensing element is used to sense the radiation in the third wavelength range. The third wavelength range is different from the first wavelength range and the second wavelength range. By bonding the first substrate above the second substrate, the first radiation sensing element in the first substrate and the corresponding second radiation sensing element in the second substrate below the first radiation sensing element constitute the first pixel unit, and the third radiation sensing element in the first substrate and the corresponding fourth radiation sensing element in the second substrate below the third radiation sensing element constitute the second pixel unit. The first pixel unit and the second pixel unit are alternately arranged as a pixel array.

In some embodiments, the wavelengths of the first wavelength range and the third wavelength range are shorter than those of the second wavelength range.

In some embodiments, the method 700 may also include a step 702. In the step 702, on the first substrate, a first radiation filter may be formed above each first radiation sensing element. The first radiation filter allows the radiation in the first and second wavelength ranges to pass through and filters out the radiation in the third wavelength range. On the first substrate, a second radiation filter may be formed above each third radiation sensing element. The second radiation filter allows the radiation in the third and second wavelength ranges to pass through and filters out the radiation in the first wavelength range.

In some embodiments, the step 704 of bonding the first substrate above the second substrate may further include: providing a light tube; and bonding the first substrate and the second substrate to the top and bottom of the light tube, respectively.

As an alternative, in some embodiments, the step 704 of bonding the first substrate above the second substrate may further include: providing a first light tube part and a second light tube part; and bonding the first substrate to the upper surface of the first light tube part, bonding the second substrate to the lower surface of the second light tube part, and bonding the lower surface of the first light tube part with the upper surface of the second light tube part.

In some embodiments, the radiation is the visible light, the first wavelength range includes the wavelengths of the green light, the second wavelength range includes the wavelengths of the red light, and the third wavelength range includes the wavelengths of the blue light.

The terms “front,” “back,” “top,” “bottom,” “over,” “under” and the like, as used herein, if any, are used for descriptive purposes and not necessarily for describing permanent relative positions. It should be understood that such terms are interchangeable under appropriate circumstances such that the embodiments of the disclosure described herein are, for example, capable of operation in other orientations than those illustrated or otherwise described herein.

The term “exemplary”, as used herein, means “serving as an example, instance, or illustration”, rather than as a “model” that would be exactly duplicated. Any implementation described herein as exemplary is not necessarily to be construed as preferred or advantageous over other implementations. Furthermore, there is no intention to be bound by any expressed or implied theory presented in the preceding technical field, background, summary or detailed description.

The term “substantially”, as used herein, is intended to encompass any slight variations due to design or manufacturing imperfections, device or component tolerances, environmental effects and/or other factors. The term “substantially” also allows for variation from a perfect or ideal case due to parasitic effects, noise, and other practical considerations that may be present in an actual implementation.

In addition, the foregoing description may refer to elements or nodes or features being “connected” or “coupled” together. As used herein, unless expressly stated otherwise, “connected” means that one element/node/feature is electrically, mechanically, logically or otherwise directly joined to (or directly communicates with) another element/node/feature. Likewise, unless expressly stated otherwise, “coupled” means that one element/node/feature may be mechanically, electrically, logically or otherwise joined to another element/node/feature in either a direct or indirect manner to permit interaction even though the two features may not be directly connected. That is, “coupled” is intended to encompass both direct and indirect joining of elements or other features, including connection with one or more intervening elements.

In addition, certain terminology, such as the terms “first”, “second” and the like, may also be used in the following description for the purpose of reference only, and thus are not intended to be limiting. For example, the terms “first”, “second” and other such numerical terms referring to structures or elements do not imply a sequence or order unless clearly indicated by the context.

Further, it should be noted that, the terms “comprise”, “include”, “have” and any other variants, as used herein, specify the presence of stated features, integers, steps, operations, elements, and/or components, but do not preclude the presence or addition of one or more other features, integers, steps, operations, elements, components, and/or groups thereof.

In this disclosure, the term “provide” is intended in a broad sense to encompass all ways of obtaining an object, thus the expression “providing an object” includes but is not limited to “purchasing”, “preparing/manufacturing”, “disposing/arranging”, “installing/assembling”, and/or “ordering” the object, or the like.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments. However, other modifications, variations and alternatives are also possible. The description and drawings are, accordingly, to be regarded in an illustrative rather than in a restrictive sense.

Although some specific embodiments of the present disclosure have been described in detail with examples, it should be understood by a person skilled in the art that the above examples are only intended to be illustrative but not to limit the scope of the present disclosure. The embodiments disclosed herein can be combined arbitrarily with each other, without departing from the scope and spirit of the present disclosure. It should be understood by a person skilled in the art that the above embodiments can be modified without departing from the scope and spirit of the present disclosure. The scope of the present disclosure is defined by the attached claims.

What is claimed is:

1. An image sensor including a pixel array, the pixel array includes alternately distributed first pixel units and second pixel units,
wherein each of the first pixel units includes:
a first radiation sensing element for sensing a radiation in a first wavelength range; and
a second radiation sensing element for sensing the radiation in a second wavelength range different from the first wavelength range, in which the first radiation sensing element is separated from the second radiation sensing element,
wherein each of the second pixel units includes:
a third radiation sensing element for sensing the radiation in a third wavelength range, which is different from the first wavelength range and the second wavelength range; and
a fourth radiation sensing element for sensing the radiation in the second wavelength range, in which the third radiation sensing element is separated from the fourth radiation sensing element.

2. The image sensor according to claim 1, wherein,
wherein each of the first pixel units further includes:
a radiation filter located above the first radiation sensing element, which allows the radiation in the first and second wavelength ranges to pass through and filters out the radiation in the third wavelength range, and
wherein each of the second pixel units further includes:
a radiation filter located above the third radiation sensing element, which allows the radiation in the third and second wavelength ranges to pass through and filters out the radiation in the first wavelength range.

3. The image sensor according to claim 1, wherein,
the first radiation sensing element and the third radiation sensing element are formed in a first substrate, and the second radiation sensing element and the fourth radiation sensing element are formed in a second substrate separated from the first substrate, the first radiation sensing element is located above the second radiation sensing element and the third radiation sensing element is located above the fourth radiation sensing element.

4. The image sensor according to claim 3, further comprising:
a light tube formed between the first substrate and the second substrate, the light tube separates the first radiation sensing element from the second radiation sensing element and separates the third radiation sensing element from the fourth radiation sensing element.

5. The image sensor according to claim 1, wherein,
the radiation is a visible light, the first wavelength range includes wavelengths of a green light, the second wavelength range includes wavelengths of a red light, and the third wavelength range includes wavelengths of a blue light.

6. The image sensor according to claim 1, further comprising:
a first charge accumulation element for accumulating charges generated by the first radiation sensing element;
a second charge accumulation element for accumulating charges generated by the second radiation sensing element;
a third charge accumulation element for accumulating charges generated by the third radiation sensing element; and
a fourth charge accumulation element for accumulating charges generated by the fourth radiation sensing element.

7. An imaging device including an image sensor according to claim 1.

8. A method for forming an image sensor comprising:
providing a first substrate in which a plurality of first radiation sensing elements and a plurality of third radiation sensing elements are formed;
providing a second substrate in which a plurality of second radiation sensing elements and a plurality of fourth radiation sensing elements are formed; and
bonding the first substrate above the second substrate,
wherein each of the first radiation sensing elements is configured to sense a radiation in a first wavelength range,
each of the second radiation sensing elements and each of the fourth radiation sensing elements are configured to sense the radiation in a second wavelength range different from the first wavelength range,
each of the third radiation sensing elements is configured to sense the radiation in a third wavelength range, which is different from the first and second wavelength ranges, and
wherein, the first radiation sensing element in the first substrate and a corresponding second radiation sensing element in the second substrate under the first radiation sensing element constitute a first pixel unit, and
the third radiation sensing element in the first substrate and a corresponding fourth radiation sensing element in the second substrate under the third radiation sensing element constitute a second pixel unit, and
the first pixel unit and the second pixel unit are alternately arranged as a pixel array.

9. The method according to claim 8, further comprising:
forming, on the first substrate, a first radiation filter above each first radiation sensing element, the first radiation filter allows the radiation in the first and second wavelength ranges to pass through and filters out the radiation in the third wavelength range, and
forming, on the first substrate, a second radiation filter above each third radiation sensing element, the second radiation filter allows the radiation in the third and second wavelength ranges to pass through and filters out the radiation in the first wavelength range.

10. The method according to claim 8, wherein bonding the first substrate above the second substrate includes:
providing a light tube; and
bonding the first and the second substrates above and below the light tube, respectively.

11. The method according to claim 9, wherein the radiation is a visible light, the first wavelength range includes wavelengths of a green light, the second wavelength range includes wavelengths of a red light, and the third wavelength range includes wavelengths of a blue light.
